(19) United States
(12) Patent Application Publication
(10) Pub. No.: US 2025/0391667 A1
(43) Pub. Date: Dec. 25, 2025

(54) METHOD AND APPARATUS FOR DAMASCENE ETCHING

(71) Applicant: Tokyo Electron Limited, Tokyo (JP)

(72) Inventors: Peng Wang, Albany, NY (US); Daniel Santos Rivera, Albany, NY (US); Ryo Matsubara, Albany, NY (US)

(21) Appl. No.: 18/753,777

(22) Filed: Jun. 25, 2024

(51) Int. Cl. H01L 21/311; H01L 21/67

(52) U.S. Cl. CPC H01L 21/31116; H01L 21/67069

(57) ABSTRACT

A method for etching a wafer includes providing the wafer in a chamber of an etching apparatus. The wafer includes a low-k dielectric material layer, a dielectric hard mask layer over the dielectric material layer, and a tungsten-based metal hard mask layer over the dielectric hard mask layer. The method further includes etching the tungsten-based metal hard mask layer by a first etchant gas in the chamber, and etching the dielectric hard mask layer by a second etchant gas in the chamber. Therefore, the etchings of the metal hard mask layer and the dielectric hard mask layer can be performed in the single same etching apparatus, thereby advantageously saving the cost and time of the etching processes.

### TECHNICAL FIELD

The present application generally relates to the field of etching semiconductor wafers.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. In semiconductor manufacturing, etching processes (such as Damascene etching) are frequently used and can indeed be costly due to factors, such as equipment costs, chemical costs, process complexity, and cleaning operations. Thus, etching apparatuses and methods with reduced costs and simplified processes are highly demanded.

### SUMMARY

In an aspect, a method may include providing a wafer in a chamber of an etching apparatus, the wafer comprising a low-k dielectric material layer, a dielectric hard mask layer over the dielectric material layer, and a tungsten-based metal hard mask layer over the dielectric hard mask layer, and the metal hard mask layer may comprising a pattern; etching the metal hard mask layer by a first etchant gas in the chamber; and etching the dielectric hard mask layer by a second etchant gas in the chamber.

In some embodiments, the method further includes after completing the etching of the dielectric hard mask layer, etching the dielectric material layer under the dielectric hard mask layer by the second etchant gas in the chamber. In some embodiments, the etching of the dielectric material layer stops upon reaching an etch-stop-layer (ESL) disposed under the dielectric material layer. In some embodiments, the tungsten-based metal hard mask layer includes Si₃N₄. In some embodiments, the first etchant gas is a fluorine-based etchant gas that is selected from a group consisting of SF₆, HF, CF₄, C₂F₆, CHF₃, NF₃, or WF₆. In some embodiments, the second etchant gas is a carbon-based etchant gas that is selected from a group consisting of CF₄, CHF₃, CH₂F₂, CH₃F, C₄F₆, or C₄F₈.

In another aspect, an etching apparatus may include a chamber; a wafer holder to hold a wafer in the chamber, the wafter including a low-k dielectric material layer, a dielectric hard mask layer over the dielectric material layer, and a tungsten-based metal hard mask layer over the dielectric hard mask layer, and the metal hard mask layer may include a pattern; a first etchant gas inlet mounted to the chamber to introduce therein a first etchant gas configured to etch the tungsten-based metal hard mask layer; and a second etchant gas inlet mounted to the chamber to introduce therein a second etchant gas configured to etch the dielectric hard mask layer.

In some embodiments, the etching apparatus further includes a third etchant gas inlet mounted to the chamber to introduce therein a third etchant gas configured to etch the low-k dielectric material layer. In some embodiments, the etching apparatus further includes a purge gas inlet mounted to the chamber to introduce therein a purge gas to purge the chamber. In some embodiments, the etching apparatus further includes a vacuum exhaust outlet mounted to the chamber and connected to a vacuum pump.

In yet another aspect, an etching system may include an etching apparatus, a first etchant gas supply, and a second etchant gas supply. The etching apparatus includes: a chamber; a wafer holder to hold a wafer in the chamber, the wafter including a low-k dielectric material layer, a dielectric hard mask layer over the low-k dielectric material layer, and a tungsten-based metal hard mask layer over the dielectric hard mask layer, and the metal hard mask layer including at least a pattern; a first etchant gas inlet mounted to the chamber to introduce therein a first etchant gas configured to etch the tungsten-based metal hard mask layer; and a second etchant gas inlet mounted to the chamber to introduce therein a second etchant gas configured to etch the dielectric hard mask layer. The first etchant gas supply is connected to the first etchant gas inlet. The second etchant gas supply is connected to the second etchant gas inlet.

In some embodiments, the first etchant gas inlet includes a first valve to control the first etchant gas introduced into the chamber, and the second gas inlet includes a second valve to control the second etchant gas introduced into the chamber.

Implementations of the described techniques may include hardware, a method or process, or a computer tangible medium for performing the process.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view illustrating a wafer including at least a dielectric hard mask (DHM) layer and a tungsten-based metal hard mask (MHM) layer over a dielectric layer, according to some embodiments.

FIGS. 2A and 2B are cross-sectional views respectively illustrating two etching processes of the wafer in FIG. 1, according to some embodiments.

FIG. 3A is a first photo illustrating the wafer in FIG. 2A after the tungsten-based MHM layer has been etched, according to some embodiments.

FIG. 3B is a second photo illustrating the wafer in FIG. 2B after both the tungsten-based MHM layer and the DHM layer, as well as portions of a dielectric layer under the DHM layer, have been etched, according to some embodiments.

FIG. 4 is a schematic view of a system for etching a wafer including at least a DHM layer and a tungsten-based MHM layer over a dielectric layer, according to some embodiments.

FIG. 5 is a flowchart illustrating a method for etching a wafer including at least a DHM layer and a tungsten-based MHM layer over a dielectric layer by using at least two etchant gases all in a same etching apparatus, according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact. There are also embodiments in which additional features may be formed between the first and second features such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature’s relationship to another element or feature as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Traditionally, a Back-End-Of-Line (BEOL) damascene etching (e.g., 28 nm node and beyond) involves several separately performed processes in different processing apparatuses, for example, a metal hard mask (MHM) etching process performed in a conductor etching apparatus, a wet cleaning process performed in a cleaning apparatus, and a low-k dielectric hard mask (DHM) etching process performed in a dielectric etching apparatus, and thereby causing high costs and long processing time due to the needed many processing apparatuses, wafer transportations, wafer idle time and/or Q-time. Thus, improved etching methods and apparatuses with less costs and shorter processing time are needed.

TiN has been a logic BEOL metal hard mask (MHM) material for at least 28 nm node. The via or trench patterns are first transferred (etched) into TiN MHM with corrosive gases such as Cl₂ which is only available in conductor etcher, after a wet clean and strict Q-time (wafer idle time in a FOUP between prior and next processes) control, completed after low-k etch in dielectric etcher. This process requires as least three major processes/tools, with relatively higher process cost and total process time. In recent years, the industry is gradually migrating the MHM material in logic BEOL critical metal layers from TiN to tungsten-based material. Etching tungsten-based MHM does not necessarily require corrosive gases, which makes it possible to perform the tungsten-based MHM etching and low-k dielectric etching all in the same dielectric etching apparatus, skipping the wet cleaning processing therebetween. This solution will save the tool cost (e.g., by reducing three processing apparatuses or tools into one processing apparatus or tool) and processing time (e.g., by reducing the wafer transportation time and Q-time between etching processes).

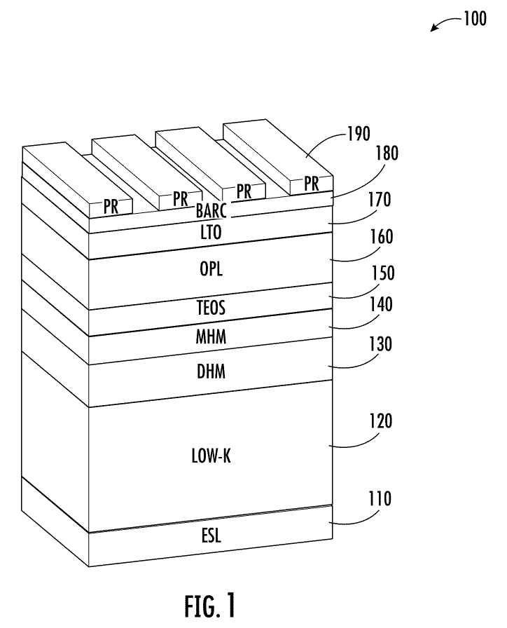

FIG. 1 is a cross-sectional view illustrating a wafer 100 (before etching) including at least a dielectric hard mask (DHM) layer 130 and a tungsten-based (or W-based) hard mask (MHM) layer 140 over a dielectric layer 120 that will be etched by using etchant gases according to some embodiments. The wafer 100 is merely an example wafter, a wafer with less or more layers or components is also within the scope of the present disclosure.

As shown in FIG. 1, in some embodiments, before etching the tungsten-based MHM layer 140 and the DHM layer 130, the wafer 100 includes an etch-stop-layer (ESL) 110, a low-k dielectric material layer 120 over the ESL 110, a DHM layer 130 over the low-k dielectric material layer 120, and a MHM layer 140 over the DHM 130. In some embodiments, a material of the low-k dielectric material layer 120 includes an organic polymer (such as polyimide, benzocyclobutene (BCB), and fluorinated polymer), as well as an inorganic material (such as porous silica, also known as porous SiO₂, and carbon-doped oxide). In some embodiments, the DHM 130 includes Si₃N₄, SiON, SiO₂, amorphous carbon, and fluorinated polymer (such as perfluoropolyether (PFPE) or perfluorocyclobutane (PFCB)). In some embodiments, the tungsten-based MHM layer 140 is tungsten nitride (WNx). Tungsten nitride is a compound of tungsten and nitrogen, has excellent etch resistance and thermal stability, and thus is suitable for use as a hard mask material in etching processes.

Also as shown in FIG. 1, in some embodiments, before etching the tungsten-based MHM layer 140 and the DHM layer 130, the wafer 100 further includes a Tetraethyl orthosilicate (TEOS) layer 150 over the tungsten-based MHM 140, an Organic Planarization Layer (OPL) 160 over the TEOS layer 150, a Low Temperature Oxide (LTO) layer 170 over the OPL 160, a Bottom Anti-Reflective Coating (BARC) layer 180 over the LTO 170, and a photo resist (PR) layer 190 over the BARC layer 180. The TEOS layer 150, as a chemical compound, may function as a precursor for depositing the LTO layer 170 through a process called chemical vapor deposition (CVD). The OPL 160 may function to achieve planarization of the wafer. The BARC layer 180 may function to minimize reflection of light from the underlying substrate during photolithography, thereby improving the patterning accuracy and reducing defects in semiconductor devices. As shown in FIG. 1, the PR layer 190 includes some patterns or openings that can be formed by, e.g., photolithography, etchings (such as wet or dry etchings), and (chemical mechanical polishing) CMP processes.

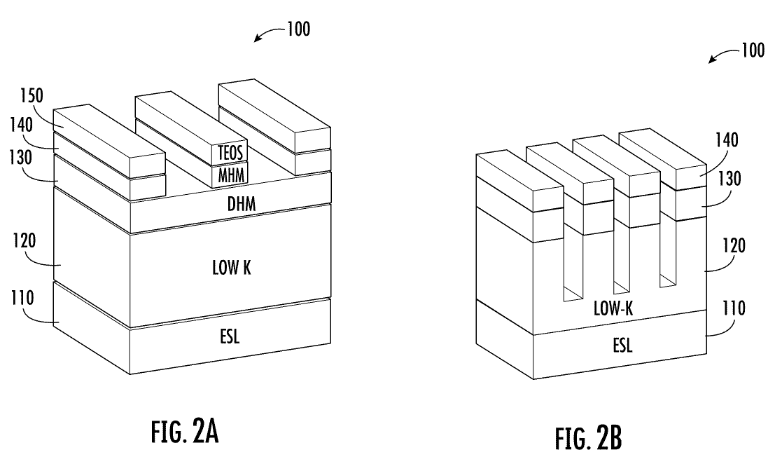

FIGS. 2A and 2B are cross-sectional views illustrating two of the etching processes of the wafer 100 in FIG. 1 according to some embodiments. FIG. 2A is a cross-sectional view illustrating a process of etching the tungsten-based MHM layer 140 of the wafer 100 in FIG. 1 according to some embodiments. FIG. 2B is a cross-sectional view illustrating another process of etching the DHM layer 130 under the tungsten-based MHM layer 140 of the wafer 100 in FIG. 1 according to some embodiments. In some embodiments, before etching the tungsten-based MHM layer 140, the patterns or openings in the PR layer 190 can be already transferred to the TEOS layer 150 through some etching processes. Details for etching the BARC layer 180, the LTO layer170, the OPL layer 160, and the TEOS layer 150) are omitted here.

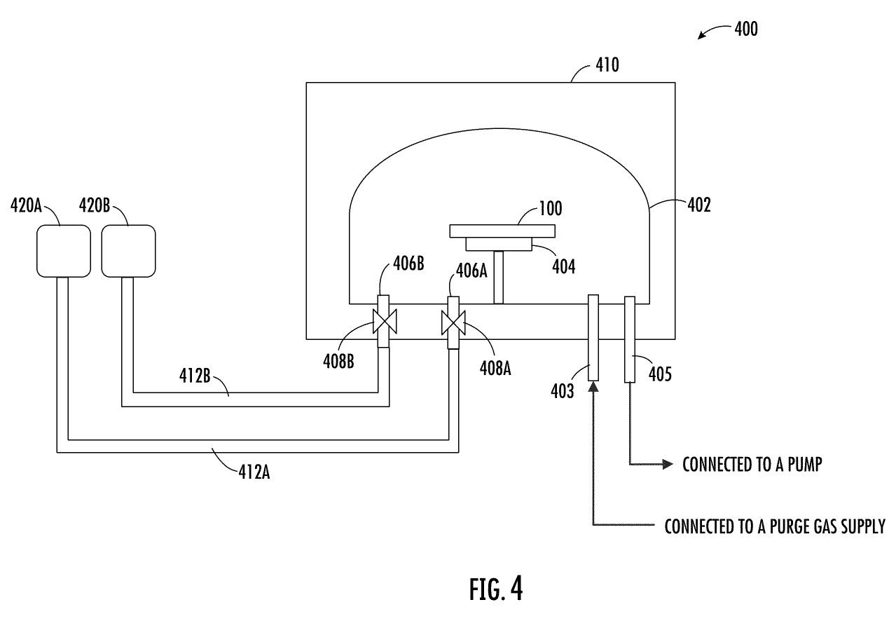

As shown in FIG. 2A, the TEOS layer 150 with patterns or openings can be used as a mask for etching the tungsten-based MHM layer 140 under the TEOS layer 150. In some embodiments, the process of etching the tungsten-based MHM layer 140 is performed in a chamber of an etching apparatus (as shown in FIG. 4) by using a first etchant gas. In some embodiments, the first etchant gas is a fluorine-based etchant gas. In some embodiments, the fluorine-based etchant gas is selected from a group consisting of SF₆, HF, CF₄, C₂F₆, CHF₃, NF₃, or WF₆.

As shown in FIG. 2B, the tungsten-based MHM 140 with patterns or openings can be used as a mask for etching the DHM layer 130 under the tungsten-based MHM layer 140. In some embodiments, the process of etching the DHM layer 130 is performed in the same chamber of the same etching apparatus for etching the tungsten-based MHM 140 (as shown in FIG. 4) by using a second etchant gas. In some embodiments, the second etchant gas is a carbon-based etchant gas. In some embodiments, the carbon based etchant gas is selected from a group consisting of CF₄, CHF₃, CH₂F₂, CH₃F, C₄F₆, C₄F₈. In some embodiments, portions of the low-k dielectric layer 120 are also etched or opened by the second etchant gas, during which the tungsten-based MHM layer 140 with patterns or openings functions as the etching mask.

As such, a single etching apparatus (as shown in FIG. 4) can be used to etch the tungsten-based MHM layer 140 by the first etchant gas and then to etch the DHM layer 130 by the second etchant gas in sequence, there is no need for an additional cleaning apparatus to perform a wet clean between these etching processes, and there is no need for a vacuum break between these etching processes, thereby advantageously reducing etching apparatuses, etching cost and Q-time between these etching processes.

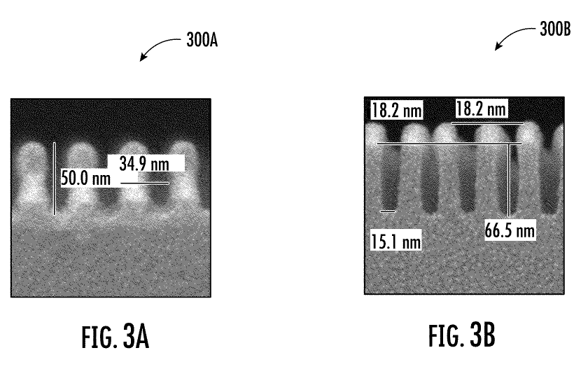

FIG. 3A is a first photo 300A illustrating the wafer 100 in FIG. 1 after the tungsten-based MHM layer 140 has been etched by the first etchant gas as explained with respect to FIG. 2A according to some embodiments. FIG. 3B is a second photo 300B illustrating the wafer 100 in FIG. 1 after both the tungsten-based MHM layer 140 and the DHM layer 130 have been etched according to some embodiments. As shown in FIGS. 2B and 3B, portions of the low-k dielectric layer 120 are also etched by the second etchant gas, during which the tungsten-based MHM layer 140 with patterns functions as the etching mask.

FIG. 4 is a schematic view of an etching system 400 for etching a wafer 100 including at least a DHM layer 130 (in FIG. 1) and a tungsten-based MHM layer 140 (in FIG. 1) over a dielectric layer 120 (in FIG. 1) according to some embodiments. In some embodiments, as shown in FIG. 4, the etching system 400 includes an etching apparatus 410 and a plurality of etchant gas supplies 420 (such as a first etchant gas supply 420A and a second etchant gas supply 420B) respectively connected to the etching apparatus 410. Even though only the first etchant gas supply 420A and the second etchant gas supply 420B are shown in FIG. 4, the etching system 400 can include more than two etchant gas supplies for etching more than two layers of the wafer without departing from the spirit of the present disclosure.

As shown in FIG. 4, in some embodiments, the etching apparatus 410 includes a chamber 402, and a wafer holder 404 to hold a wafer 100 in the chamber 402. As shown in FIG. 2A, the wafter 100 includes at least a low-k dielectric material layer 120, a DHM layer 130 over the low-k dielectric material layer 120, a tungsten-based MHM layer 140 over the DHM layer 130, and a TEOS layer 150 over the tungsten-based MHM layer 140, and the TEOS layer 150 includes one or more patterns already formed therethrough and can be used as a mask for etching the tungsten-based MHM layer 140 thereunder.

As shown in FIG. 4, in some embodiments, the etching apparatus 410 further includes a first etchant gas inlet 406A mounted to the chamber 402 to introduce therein a first etchant gas configured to etch the tungsten-based MHM layer 140 (in FIG. 1), and a second etchant gas inlet 406B mounted to the chamber 402 to introduce therein a second etchant gas configured to etch the DMM layer 130 (in FIG. 1). In some embodiments, the first etchant gas supply 420A is connected to the first etchant gas inlet 406A through a first etchant gas pipe 412A, and the second etchant gas supply 420B is connected to the second etchant gas inlet 406B through a second etchant gas pipe 412B. In some embodiments, the first etchant gas inlet 406A includes a first valve 408A to control the first etchant gas to be introduced into the chamber 402, and the second gas inlet 406B includes a second valve 408B to control the second etchant gas to be introduced into the chamber 402. As shown in FIG. 4, in some embodiments, the etching apparatus 410 further includes a purge gas inlet 403 mounted to the chamber 402 to introduce therein a purge gas from a purge gas supply (not shown) to purge the chamber 402, and a vacuum exhaust outlet 405 mounted to the chamber 402 and connected to a vacuum pump (not shown) to exhaust gases from the chamber 402 and to keep a suitable air pressure in the chamber 402.

In some embodiments, the first etchant gas is a fluorine-based etchant gas selected from a group consisting of SF₆, HF, CF₄, C₂F₆, CHF₃, NF₃, or WF₆, and is configured to be introduced into the chamber 402 to etch the tungsten-based MHM layer 140. In some embodiments, the second etchant gas is a carbon based etchant gas selected from a group consisting of CF₄, CHF₃, CH₂F₂, CH₃F, C₄F₆, C₄F₈, and is configured to be introduced into the chamber 402 to etch the DHM layer 130 and the low-k dielectric layer 120 thereunder.

As such, the single etching apparatus 410 can be used to etch in sequence the tungsten-based MHM layer 140 by the first etchant gas and etch the DHM layer 130 by the second etchant gas, there is no need for an additional cleaning apparatus to perform a wet cleaning between these etching processes, and there is no need for a vacuum break between these etching processes, thereby advantageously reducing processing apparatuses, etching cost, and Q-time between various processes.

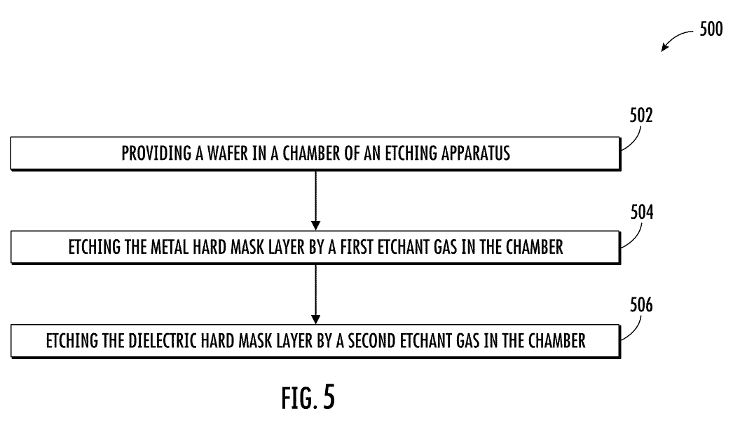

FIG. 5 is a flowchart illustrating a method 500 of etching a wafer 100 including at least a dielectric hard mask (DHM) layer 130 and a metal hard mask (MHM) layer 140 over a low-k dielectric layer 120 by various etchant gases (such as a first and a second etchant gases) according to some embodiments. It is understood that additional operations can be provided before, during, and after processes discussed in FIG. 5, and some of the operations described below can be replaced or eliminated, for additional embodiments of the method. The order of the operations/processes may be interchangeable and at least some of the operations or processes may be performed in a different sequence.

Referring to FIGS. 2A, 4 and 5, in operation 502, a wafer 100 is provided in a chamber 402 of an etching apparatus 410. In some embodiments, the wafter 100 includes at least a low-k dielectric material layer 120, a DHM layer 130 over the low-k dielectric material layer 120, a tungsten-based MHM layer 140 over the DHM layer 130, and a TEOS layer 150 over the tungsten-based MHM layer 140, and the TEOS layer 150 includes one or more patterns or openings already formed therethrough and can be used as a mask for etching the tungsten-based MHM layer 140 thereunder. In some embodiments, the tungsten-based MHM layer 140 includes tungsten nitride (WNx).

Referring to FIGS. 2A, 4 and 5, in operation 504, the tungsten-based MHM layer 140 is etched by a first etchant gas in the chamber 402 of the etching apparatus 410. In some embodiments, the first etchant gas is a fluorine-based etchant gas that is selected from a group consisting of SF₆, HF, CF₄, C₂F₆, CHF₃, NF₃, or WF₆.

Referring to FIGS. 2B, 4 and 5, in operation 506, the DHM layer 130 is etched by a second etchant gas in the chamber 402 of the etching apparatus 410. In some embodiments, the second etchant gas is a carbon-based etchant gas that is selected from a group consisting of CF₄, CHF₃, CH₂F₂, CH₃F, C₄F₆, C₄F₈.

In some embodiments, after completing the etching of the DHM layer 130, the dielectric material layer 120 under the DHM layer 130 is etched by the second etchant gas in the chamber 402 of the etching apparatus 410. In some embodiments, the etching of the dielectric material layer 120 stops, upon reaching an etch-stop-layer (ESL) 110 that is disposed under the dielectric material layer 120.

In some embodiments, the etching apparatus 410 is a dielectric etching apparatus, which can be used to etch any of the tungsten-based MHM layer 140 and the DHM layer 130. Since the etchings of the tungsten-based MHM layer and the DHM layer are performed in sequence respectively by a first and a second etchant gases all in one single etching apparatus, the number of processing apparatuses is reduced (e.g., to one), there is no need for an additional cleaning apparatus, and vacuum breaks and wafer transportations are minimized to thus reduce the chances of defects (e.g., particles, post-etch residue, etc.), thereby resulting in improved quality and reduced cost of the products.

What has been described and illustrated herein is an example along with some of its variations. The terms, descriptions and figures used herein are set forth by way of illustration only and are not meant as limitations. Many variations are possible within the spirit and scope of the subject matter, which is intended to be defined by the following claims 1-20 and their equivalents, in which all terms are meant in their broadest reasonable sense unless otherwise indicated.

What is claimed is:

1. A method comprising:
providing a wafer in a chamber of an etching apparatus, the wafer comprising a dielectric material layer, a dielectric hard mask layer over the dielectric material layer, and a tungsten-based metal hard mask layer over the dielectric hard mask layer;
etching, in the chamber, the metal hard mask layer by a first etchant gas; and
etching, in the chamber, the dielectric hard mask layer by a second etchant gas.

2. The method of claim 1, further comprising:
after completing the etching of the dielectric hard mask layer, etching the dielectric material layer under the dielectric hard mask layer by the second etchant gas in the chamber.

3. The method of claim 2, wherein the etching of the dielectric material layer stops upon reaching an etch-stop-layer disposed under the dielectric material layer.

4. The method of claim 1, wherein the dielectric material layer comprises a low-k dielectric material, and wherein the tungsten-based metal hard mask layer comprises tungsten nitride (WNx).

5. The method of claim 1, wherein the first etchant gas is a fluorine-based etchant gas.

6. The method of claim 5, wherein the fluorine-based etchant gas is selected from a group consisting of SF₆, HF, CF₄ ,C₂F₆, CHF₃, NF₃, or WF₆.

7. The method of claim 1, wherein the second etchant gas is a carbon-based etchant gas.

8. The method of claim 6, wherein the carbon based etchant gas is selected from a group consisting of CF₄,CHF₃,CH₂F₂, CH₃F, C₄F₆, or C₄F₈.

9. An etching apparatus, comprising:
a chamber;
a wafer holder to hold a wafer in the chamber, wherein the wafter comprises a low-k dielectric material layer, a dielectric hard mask layer over the dielectric material layer, and a tungsten-based metal hard mask layer over the dielectric hard mask layer;
a first etchant gas inlet mounted to the chamber to introduce therein a first etchant gas configured to etch the tungsten-based metal hard mask layer; and
a second etchant gas inlet mounted to the chamber to introduce therein a second etchant gas configured to etch the dielectric hard mask layer.

10. The apparatus of claim 9, further comprising:
a third etchant gas inlet mounted to the chamber to introduce therein a third etchant gas configured to etch the low-k dielectric material layer.

11. The apparatus of claim 9, wherein the tungsten-based metal hard mask layer comprises tungsten nitride (WNx).

12. The apparatus of claim 9, wherein the first etchant gas is a fluorine-based etchant gas selected from a group consisting of SF₆, HF, CF₄, C₂F₆, CHF₃, NF₃, or WF₆.

13. The apparatus of claim 9, wherein the second etchant gas is a carbon based etchant gas selected from a group consisting of CF₄, CHF₃, CH₂F₂,CH₃F, C₄F₆, or C₄F₈.

14. The apparatus of claim 9, further comprising a purge gas inlet mounted to the chamber to introduce therein a purge gas to purge the chamber.

15. The apparatus of claim 9, further comprising a vacuum exhaust outlet mounted to the chamber and connected to a vacuum pump.

16. An etching system comprising:
an etching apparatus comprising:
a chamber;
a wafer holder to hold a wafer in the chamber, wherein the wafter comprises a low-k dielectric material layer, a dielectric hard mask layer over the low-k dielectric material layer, and a tungsten-based metal hard mask layer over the dielectric hard mask layer;
a first etchant gas inlet mounted to the chamber to introduce therein a first etchant gas configured to etch the tungsten-based metal hard mask layer; and
a second etchant gas inlet mounted to the chamber to introduce therein a second etchant gas configured to etch the dielectric hard mask layer;
a first etchant gas supply connected to the first etchant gas inlet; and
a second etchant gas supply connected to the second etchant gas inlet.

17. The system of claim 16, wherein the first etchant gas inlet comprises a first valve to control the first etchant gas introduced into the chamber, and wherein the second gas inlet comprises a second valve to control the second etchant gas introduced into the chamber.

18. The system of claim 16, wherein the tungsten-based metal hard mask layer comprises tungsten nitride (WNx).

19. The system of claim 16, wherein the first etchant gas is a fluorine-based etchant gas selected from a group consisting of SF₆, HF, CF₄, C₂F₆, CHF₃, NF₃ or WF₆.

20. The system of claim 16, wherein the second etchant gas is a carbon based etchant gas selected from a group consisting of CF₄, CHF₃, CH₂F₂, CH₃F, C₄F_{6,} or C₄F₈.
